(19) United States
(12) Patent Application Publication
(10) Pub. No.: US 2016/0197298 A1
(43) Pub. Date: Jul. 7, 2016

(54) ORGANIC/INORGANIC ELECTROLUMINESCENT DEVICE

(71) Applicant: NATIONAL CENTRAL UNIVERSITY, TAOYUAN COUNTY (TW)

(72) Inventors: CHENG-YI LIU, TAOYUAN COUNTY (TW); YEN-JU WU, TAICHUNG CITY (TW)

(21) Appl. No.: 15/002,569

(22) Filed: Jan. 21, 2016

Related U.S. Application Data
(63) Continuation-in-part of application No. 14/589,048, filed on Jan. 5, 2015.

(51) Int. Cl. H01L 51/50; H01L 33/06; H01L 33/32

(52) U.S. Cl. CPC H01L 51/504; H01L 33/32; H01L 33/06; H01L 51/0039

(57) ABSTRACT

An p-type organic/p-type inorganic electroluminescent device includes an anode, a p-type organic compound layer connected to the anode, a cathode, and a p-type inorganic compound layer connected to the cathode. The p-type organic compound layer and the p-type inorganic compound layer are in direct contact with one another to form an p-type organic/p-type inorganic hetero-junction therebetween, and thereby light generated at the p-type organic/p-type inorganic hetero-junction with electrons and holes recombination at the hetero-junction under applied forward voltage.

### CROSS-REFERENCE TO RELATED APPLICATION

This is a continuation-in-part of co-pending application Ser. No. 14/589,048, filed on Jan. 5, 2015, currently pending.

### BACKGROUND OF THE INVENTION

1. Field of the Invention

The present invention relates to an electroluminescent device, and more particularly to an electroluminescent device that emits light via a p-type organic/p-type inorganic hetero-junction.

2. Description of the Related Art

Of all electroluminescent devices, an organic electroluminescent device using an organic compound as a light-emitting body has, for example, the characteristics that the device has high photoluminescence properties and can easily provide a desired emission color by selecting an appropriate light emitting material. Accordingly, the organic electroluminescent device has been actively developed as a next-generation display. However, the organic electroluminescent devices generally have poor electrical properties and are driven at a higher voltage than at which an inorganic electroluminescent device is driven.

In general, an organic electroluminescent device includes two electrodes and an organic compound layer disposed between the electrodes. When a voltage is applied to the organic electroluminescent device, electrons and holes are injected into the organic compound layer from two electrodes to convert electric currents into visible light. One example of the organic electroluminescent devices is illustrated in U.S. Pat. No. 7,365,360, in which an n-type organic compound layer and a p-type organic compound layer are employed.

On the other hand, inorganic electroluminescent devices, such as GaN-based LEDs, have also been actively developed for decades. In general, the inorganic electroluminescent device is a basic PN-junction diode, which emits light when activated. When a suitable voltage is applied, electrons are able to recombine with electron holes within the device, releasing energy in the form of photons. The color of the light is determined by the energy band gap of the semiconductor which is limited with short spectral coverage.

We are thinking of a possibility to combine the advantages of both organic and inorganic semiconductors to form a new light source. Moreover, a white emitting diode is more than that. There are two primary ways of producing white light-emitting diodes. One is to use individual LEDs that emit three primary colors—red, green, and blue—and then mix all the colors to form white light. The other is to use a phosphor material to convert monochromatic light from a blue or UV LED to broad-spectrum white light. However, either way involves problems to be solved that the device cannot be manufactured at a low cost and does not have a sufficient luminous efficiency and lifetime owing to the phosphor if used.

### SUMMARY OF THE INVENTION

It is an object of the present invention to provide an electroluminescent device with a new light emission mechanism, namely an p-type organic/p-type inorganic hetero-junction.

Specifically, the p-type organic/p-type inorganic electroluminescent device includes a first electrode, a p-type organic compound layer directly or indirectly connected to the first electrode, a second electrode, and a p-type inorganic compound layer directly or indirectly connected to the second electrode. The p-type organic compound layer and the p-type inorganic compound layer are in direct contact with one another to form a p-type organic/p-type inorganic hetero-junction there between in order to emit light, wavelength length corresponding to the organic materials ranging from 380-700 nm, using electrons and holes recombined at the p-p hetero-junction when a voltage is applied.

The present invention provides the electroluminescent device with a new white light emission mechanism, without using phosphors. Here, for example, the π-conjugated polymer, F8T2, is chosen to be the p-type organic compound by spin-coating deposition, and the p-GaN, n-GaN, and multi-quantum wells are used for the p-type, n-type, and emitting layer inorganic compound by metal organic chemical vapor deposition (MOCVD) process, separately. With the aforementioned p-type organic compound layer and the p-type inorganic compound layer, the electroluminescent device further includes a substrate, an n-type inorganic compound layer disposed on the substrate, and an emission layer disposed in between the n-type inorganic compound layer and the p-type inorganic compound layer for emitting a first, blue light of about 460 nm wavelength. In particular, the second light generated at the hetero-junction has a wavelength ranged from green to yellow of 520-650 nm wavelength. Thus, a white light can be formed by the mixture of the first light and the second light in the electroluminescent device.

Besides, it is preferable that the p-type organic compound layer further serve as a transparent conducting layer for current spreading. The foregoing and other objectives, features, and advantages of the invention will be more readily understood upon consideration of the following detailed description of the invention, taken in conjunction with the accompanying drawings.

### BRIEF DESCRIPTION OF THE DRAWINGS

FIG. 1 is a cross-sectional view of an electroluminescent device in accordance with a first embodiment of the present invention; and

FIG. 2 is a cross-sectional view of an electroluminescent device in accordance with the second embodiment of the present invention.

### DETAILED DESCRIPTION OF EMBODIMENTS

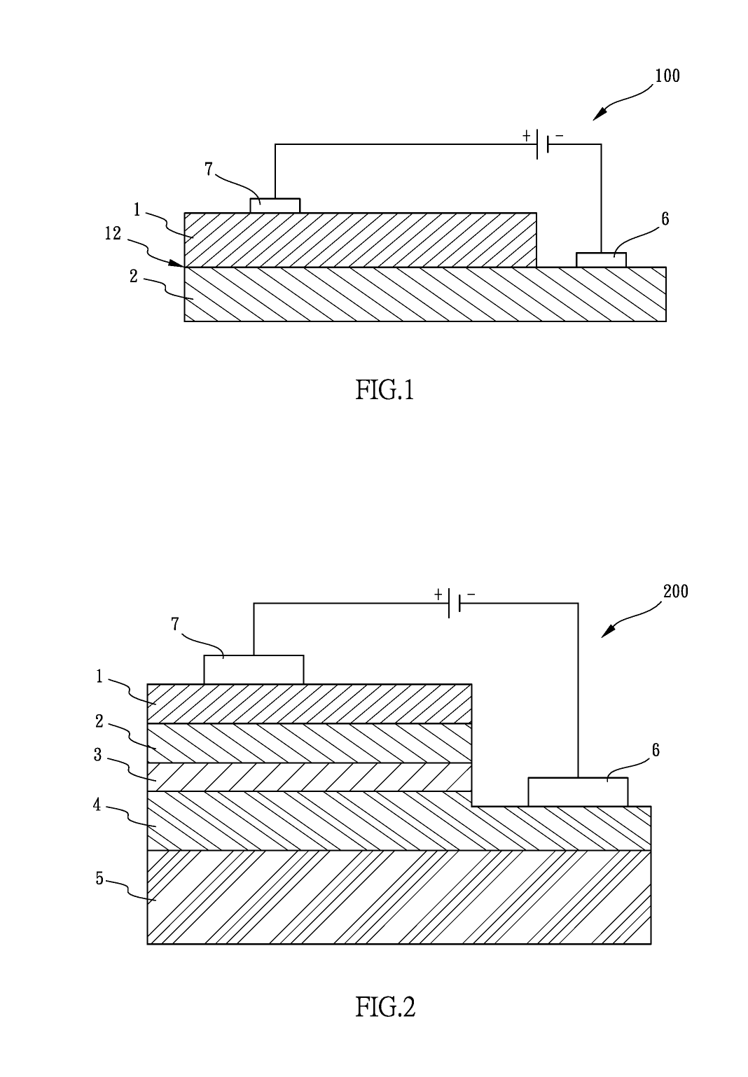

Referring to FIG. 1, there is shown a first embodiment of the p-type organic/p-type inorganic electroluminescent device 100, substantially comprising an upper p-type organic compound layer 1 and a lower p-type inorganic compound layer 2 in direct contact with each other. Furthermore, an anode 7 is disposed on the p-type organic compound layer 1 while a cathode 6 is disposed on the p-type inorganic compound layer 2.

In this manner, an p-type organic/p-type inorganic hetero-junction 12 is formed therebetween the p-type organic compound layer 1 and the p-type inorganic compound layer 2. Recombination takes place based on the mobility of the carriers at the hetero-junction between the p-type organic compound layer 1 and the p-type inorganic compound layer 2. Thus, the p-type organic/p-type inorganic electroluminescent device 100 emits light with the electrons and holes recombination at the hetero-junction 12 when a forward voltage is applied via the anode 7 and the cathode 6. In the p-type organic/p-type inorganic electroluminescent device of the present invention, by appropriately setting the band gap of the p-type organic compound layer 1 and the p-type inorganic compound layer 2, a desired emission color may be provided.

As is understood that the p-type organic compound layer 1 is an organic compound layer having p-type semiconductor properties. For example, the p-type organic compound layer 1 may be a conductive conjugated polymer, such as a fluorene-based π-conjugated polymer, and can be fabricated by spin-coating or chemical deposition process. The p-type inorganic compound layer 2, on the other hand, is an inorganic compound layer having p-type semiconductor properties. For example, the p-type inorganic compound layer 2 may comprise a GaN-based material, which is well-known in the art for a GaN-based LED, and can be fabricated by metal organic chemical vapor deposition (MOCVD), atomic layer deposition (ALD), or sputter.

As described above, the organic/inorganic electroluminescent device 100 has such excellent characteristic that the device is simple in structure and can be produced in cost-effective way, and therefore is expected to find use in a variety of applications.

FIG. 2 is a cross-sectional view illustrating an p-type organic/p-type inorganic organic/inorganic electroluminescent device 200, which is based on the first embodiment, according to a second embodiment of the present invention. The p-type organic/p-type inorganic organic/inorganic electroluminescent device 200 has a substrate 5, and an n-type inorganic compound layer 4, an emission layer 3, a p-type inorganic compound layer 2, a p-type organic compound layer 1, and an anode 7 sequentially stacked in an order on the substrate 5. Besides, a cathode 6 is disposed on the n-type inorganic compound layer 4.

The electroluminescent device 200 has a new white light emission mechanism without using phosphors. Here, the π-conjugated polymer, F8T2, is chosen to be the p-type organic compound by spin-coating process, and the p-GaN, n-GaN, and multi-quantum wells are used for the p-type, n-type, and emitting layer inorganic compound by metal organic chemical vapor deposition (MOCVD) process, separately. With the aforementioned p-type organic compound layer 1 and the p-type inorganic compound layer 2, the electroluminescent device further includes a substrate, an n-type inorganic compound layer 2 disposed on the substrate, and an emission layer disposed in between the n-type inorganic compound layer 2 and the p-type inorganic compound layer 2 for emitting a first, blue light of about 460 nm wavelength. In particular, the second light generated at the hetero-junction has a wavelength ranged from green to yellow of 520-650 nm wavelength.

The p-type organic compound layer 1 is a fluorene-based π-conjugated polymer, which can be fabricated by spin-coating, chemical vapor deposition process; the wavelength emission ranges from 380-700 nm corresponding to the chosen/adequate organic compound.

An emission layer 3, so called the multi-quantum wells, disposed in between the n-type inorganic compound layer 2 and the p-type inorganic compound layer 4 for emitting a second, blue light, the wavelength ranging from 380-480 nm corresponding from the band gap and composition of the inorganic compound. The p-type, n-type, and emitting layer 3 of GaN-based inorganic compound can be fabricated by metal organic chemical vapor deposition (MOCVD), atomic layer deposition (ALD), or sputter;

In view of the similarity between the first and second embodiments 100, 200, the parts of the second embodiment 200 that are identical to the parts of the first embodiment 100 will be given the same reference numerals as the parts of the first embodiment 100. Moreover, the descriptions of the parts of the second embodiment 200 that are identical to the parts of the first embodiment 100 may be omitted for the sake of brevity.

Briefly, the p-type organic/p-type inorganic electroluminescent device 200 is particularly configured to produce white-light emission and be produced in a cost-effective manner. In particular, two emission interfaces are employed in the organic/inorganic electroluminescent device 200. One for a blue light and the other for a green/yellow light.

More specifically, the first light emitting interface is the emission layer 3, sandwiched between the n-type inorganic compound layer 4 and the p-type inorganic compound layer 2. The emission layer 3 is a multi-quantum wells configured for emitting a first, blue light. In this case, the n-type inorganic compound layer may comprise a GaN-based material and the p-type inorganic compound layer also comprises a GaN-based material, as is known in the art.

Moreover, the second emitting interface is the hetero-junction 12 between the p-type organic compound layer 1 and the p-type inorganic compound layer 2. As is recalled from the discussion in the first embodiment 100, the second light is generated at the hetero-junction 12. The second light may be arranged to have a wavelength ranged from green to yellow, by appropriately setting the band gap of the p-type organic compound layer 1 and the p-type inorganic compound layer 2. With the first and second lights, the electroluminescent device 200 can generate a white light formed by mixture of the second, green-yellow light and the first, blue light.

By the way, the p-type organic compound layer 1 itself may serve as a transparent conducting layer for current spreading. Thus, no extra transparent conducting layer is needed.

As described above, the organic/inorganic electroluminescent device 200 of the present invention has such excellent characteristic that the white light emitting device can be produced at a low cost as compared to a conventional white LED using a phosphor material.

What is claimed is:

1. An p-type organic/p-type inorganic hetero-junction electroluminescent device, comprising:
a first electrode;
a p-type organic compound layer directly or indirectly connected to the first electrode.
a second electrode; and
a p-type inorganic compound layer directly or indirectly connected to the second electrode;
wherein the p-type organic compound layer and the p-type inorganic compound layer are in direct contact with one another to form a p-type organic/p-type inorganic hetero-junction therebetween in order to emit light with electrons and holes recombination at the hetero-junction when a forward voltage is applied.

2. A p-type organic/p-type inorganic hetero-junction electroluminescent device as recited in claim 1, wherein the first electrode is an anode, and the second electrode is a cathode.

3. A p-type organic/p-type inorganic hetero-junction electroluminescent device as recited in claim 1, wherein the p-type organic compound layer is a conductive conjugated polymer

4. A p-type organic/p-type inorganic hetero-junction electroluminescent device as recited in claim 1, wherein the p-type organic compound layer is a fluorene-based π-conjugated polymer, which can be fabricated by spin-coating, or chemical vapor deposition process; the wavelength emission ranges from 380-700 nm corresponding to the chosen/adequate organic compound.

5. A p-type organic/p-type inorganic hetero-junction electroluminescent device as recited in claim 1, wherein the p-type inorganic compound layer comprises a GaN-based material, which can be fabricated by metal organic chemical vapor deposition (MOCVD), atomic layer deposition (ALD), or sputter,

6. A p-type organic/p-type inorganic hetero-junction electroluminescent device as recited in claim 2, further comprising:
a substrate;
an n-type inorganic compound layer disposed on the substrate, wherein the p-type inorganic compound layer is connected to the second electrode via the n-type inorganic compound layer; and
an emission layer, so called the multi-quantum wells, disposed in between the n-type inorganic compound layer and the p-type inorganic compound layer for emitting a second, blue light, the wavelength ranging from 380-480 nm corresponding from the band gap of the inorganic compound. The p-type, n-type, and emitting layer of GaN-based inorganic compound can be fabricated by metal organic chemical vapor deposition (MOCVD), atomic layer deposition (ALD), or sputter;
wherein the second light generated at the hetero-junction has a wavelength ranged from green to yellow, and therefore a white light is formed by mixture of the first light and the second light in the organic/inorganic electroluminescent device.

7. An p-type organic/p-type inorganic hetero-junction electroluminescent device as recited in claim 6, wherein the emission layer is a multi-quantum well.

8. An p-type organic/p-type inorganic hetero-junction electroluminescent device as recited in claim 6, wherein the p-type organic compound layer further serves as a transparent conducting layer for current spreading.

9. An p-type organic/p-type inorganic hetero-junction electroluminescent device as recited in claim 6, wherein the p-type organic compound layer is a conductive conjugated polymer

10. An p-type organic/p-type inorganic hetero-junction electroluminescent device as recited in claim 6, wherein the n-type inorganic compound layer comprises a GaN-based material.

11. An p-type organic/p-type inorganic hetero-junction electroluminescent device as recited in claim 10, wherein the p-type inorganic compound layer comprises a GaN-based material.

12. An p-type organic/p-type inorganic hetero-junction electroluminescent device as recited in claim 11, wherein the p-type organic compound layer is a fluorene-based π-conjugated polymer.
